(19) United States
(12) Patent Application Publication
(10) Pub. No.: US 2018/0277339 A1
(43) Pub. Date: Sep. 27, 2018

(54) PLASMA PROCESSING APPARATUS

(71) Applicant: TOKYO ELECTRON LIMITED, Tokyo (JP)

(72) Inventors: Kazushi KANEKO, Kurokawa-gun (JP); Yohei ISHIDA, Kurokawa-gun (JP); Hajime TAMURA, Tokyo (JP)

(73) Assignee: TOKYO ELECTRON LIMITED, Tokyo (JP)

(21) Appl. No.: 15/922,215

(22) Filed: Mar. 15, 2018

(30) Foreign Application Priority Data
Mar. 22, 2017 (JP) 2017-055854

(51) Int. Cl. H01J 37/32; C23C 16/511

(52) U.S. Cl. CPC H01J 37/32238; H01J 37/32119; C23C 16/511; H01J 37/3222; H01J 37/3211; H01J 37/32394; H01J 37/32577

(57) ABSTRACT

A microwave generator of a plasma processing apparatus of an embodiment includes a first module, a second module, and a combiner. The first module includes a distributor which distributes a high-frequency electric signal, and outputs a plurality of high-frequency electric signals. A plurality of amplifier modules of the second module respectively amplify the plurality of high-frequency electric signals from the first module to output a plurality of microwaves. The combiner combines the plurality of microwaves from the plurality of amplifier modules to output a microwave. Each of the plurality of amplifier modules has a DC/DC converter and an amplifier. The DC/DC converter steps down the voltage of a first direct-current power from an external direct-current power supply to output a second direct-current power. The amplifier amplifies a high-frequency electric signal by using the second direct-current power to output a microwave.

### CROSS-REFERENCE TO RELATED APPLICATIONS

The present application is based on and claims the benefit of priority from Japanese Patent Application No. 2017-055854 filed on Mar. 22, 2017, the entire contents of which are incorporated herein by reference.

### FIELD

Exemplary embodiments of the present disclosure relate to a plasma processing apparatus.

### BACKGROUND

In the manufacturing of electronic devices, a plasma processing apparatus is used for plasma processing such as plasma etching on a substrate or film formation on a substrate. In the plasma processing apparatus, plasma is generated in a chamber by exciting gas supplied to the chamber. In the plasma processing apparatus, high-frequency power (electric energy) is used in order to excite the gas. For this reason, the plasma processing apparatus has a high-frequency power supply unit. Such a plasma processing apparatus is disclosed in Japanese Patent Application Laid-Open Publication No. 2004-247401.

In the plasma processing apparatus disclosed in Japanese Patent Application Laid-Open Publication No. 2004-247401, a high-frequency power supply unit has an oscillator and an amplifier. The oscillator generates a high-frequency electric signal, and the amplifier amplifies the high-frequency electric signal from the oscillator to output high-frequency power for excitation of a gas. The amplifier uses direct-current power which is supplied from a direct-current power supply unit, in the amplification of the high-frequency electric signal. The direct-current power supply unit is a switching power supply and converts commercial alternating-current power into direct-current power having a voltage suitable for the driving of the amplifier. The amplifier and the direct-current power supply unit are connected to each other through a cable.

### SUMMARY

In an aspect, a plasma processing apparatus which is provided with a microwave generator is provided. The microwave generator is provided with a first module, a second module, and a combiner. The first module includes a distributor configured to distributes a high-frequency electric signal, and is configured to output a plurality of high-frequency electric signals. The second module includes a plurality of amplifier modules. The plurality of amplifier modules is configured to amplify the plurality of high-frequency electric signals from the first module to output a plurality of microwaves, respectively. The combiner combines the plurality of microwaves from the plurality of amplifier modules by spatial combining to output a microwave. Each of the plurality of amplifier modules has a DC/DC converter and an amplifier. The DC/DC converter is configured to steps down a voltage of a first direct-current power from an external direct-current power supply to outputs a second direct-current power. The amplifier is configured to amplify a corresponding high-frequency electric signal among the plurality of high-frequency electric signals from the first module by using the second direct-current power to output a microwave.

The foregoing summary is illustrative only and is not intended to be in any way limiting. In addition to the illustrative aspects, exemplary embodiments, and features described above, further aspects, exemplary embodiments, and features will become apparent by reference to the drawings and the following detailed description.

### BRIEF DESCRIPTION OF THE DRAWINGS

FIG. 1 is a diagram schematically illustrating a plasma processing apparatus according to an exemplary embodiment.

FIG. 2 is a partially broken view illustrating the plasma processing apparatus illustrated in FIG. 1.

FIG. 3 is a diagram illustrating a waveguide part of the plasma processing apparatus illustrated in FIG. 1, together with a microwave generator and a control unit.

FIG. 4 is a diagram illustrating a configuration of the microwave generator of the plasma processing apparatus illustrated in FIG. 1.

FIG. 5 is a diagram for explaining the principle of generation of a high-frequency electric signal in a waveform generator illustrated in FIG. 4.

FIG. 6 is a perspective view of the microwave generator according to an exemplary embodiment.

FIG. 7 is an exploded perspective view of a main unit of the microwave generator illustrated in FIG. 6.

FIG. 8 is a plan view illustrating the bottom surface side of a first module of the microwave generator illustrated in FIG. 6.

FIG. 9 is a plan view of a second module of the microwave generator illustrated in FIG. 6.

FIG. 10 is a side view of the second module of the microwave generator illustrated in FIG. 6.

FIG. 11 is a side view illustrating a cooling structure of the second module of the microwave generator illustrated in FIG. 6.

FIG. 12 is a sectional view illustrating a combiner of the main unit illustrated in FIG. 7.

FIG. 13 is a plan view illustrating the combiner of the main unit illustrated in FIG. 7.

FIG. 14 is a diagram schematically illustrating a plasma processing apparatus according to another exemplary embodiment.

### DETAILED DESCRIPTION

In the following detailed description, reference is made to the accompanying drawings, which form a part hereof. The exemplary embodiments described in the detailed description, drawing, and claims are not meant to be limiting. Other exemplary embodiments may be utilized, and other changes may be made, without departing from the spirit or scope of the subject matter presented here.

As one type of plasma processing apparatus, a plasma processing apparatus which excites gas in a chamber by a microwave is used. In this type of plasma processing apparatus, a microwave generator having a magnetron, or a microwave generator having an amplifier which performs amplification by using a semiconductor element is used. The latter, that is, the microwave generator having an amplifier generates a microwave by amplifying a high-frequency electric signal by using direct-current power.

Incidentally, in a plasma processing apparatus, an area in which it is disposed is required to be small. For example, in a case where a plasma processing apparatus is used in a clean room, an area which is occupied by the plasma processing apparatus in the clean room is required to be small. To this end, the size of the microwave generator of the plasma processing apparatus is required to be small. Further, the weight of the microwave generator of the plasma processing apparatus is also required to be small.

In an aspect, a plasma processing apparatus which is provided with a microwave generator is provided. The microwave generator is provided with a first module, a second module, and a combiner. The first module includes a distributor configured to distributes a high-frequency electric signal, and is configured to output a plurality of high-frequency electric signals. The second module includes a plurality of amplifier modules. The plurality of amplifier modules is configured to amplify the plurality of high-frequency electric signals from the first module to output a plurality of microwaves, respectively. The combiner combines the plurality of microwaves from the plurality of amplifier modules by spatial combining to output a microwave. Each of the plurality of amplifier modules has a DC/DC converter and an amplifier. The DC/DC converter is configured to steps down a voltage of a first direct-current power from an external direct-current power supply to outputs a second direct-current power. The amplifier is configured to amplify a corresponding high-frequency electric signal among the plurality of high-frequency electric signals from the first module by using the second direct-current power to output a microwave.

In order to amplify a high-frequency electric signal in an amplifier, direct-current power having a voltage suitable for the driving of the amplifier must be provided to the amplifier. One measure for obtaining such direct-current power is to integrate a switching power supply with a microwave generator. The switching power supply is a switching power supply which converts a commercial alternating-current power into a direct-current power having a voltage suitable for driving the amplifier. A microwave generator integrated with such a switching power supply becomes large in both the size and the weight thereof. Another measure is to provide a switching power supply which converts commercial alternating-current power into direct-current power having a voltage suitable for driving an amplifier as a separate body from a microwave generator and connect the switching power supply and the microwave generator by a cable for power transmission. However, in this measure, since a current flowing through the cable becomes large, the cross-sectional area of the cable becomes large and the weight of the cable becomes heavy. Therefore, handling of the cable is not easy.

In the microwave generator of the plasma processing apparatus according to the aspect, a plurality of microwaves generated by amplifying a high-frequency electric signal by an amplifier in each of the plurality of amplifier modules are combined and a microwave is output. In the microwave generator, each amplifier module has the DC/DC converter and the amplifier. The DC/DC converter receives the first direct-current power from an external direct-current power supply, that is, the switching power supply for converting a commercial alternating-current power into a direct-current power, and provides the second direct-current power obtained by stepping down the voltage of the first direct-current power to the amplifier. That is, the microwave generator of the plasma processing apparatus according to the aspect converts the first direct-current power from a separate direct-current power supply (switching power supply) into low-voltage direct-current power in the DC/DC converter of each amplifier module and uses the direct-current power in the amplifier. Therefore, the microwave generator becomes small in both the size and the weight thereof. Further, in the microwave generator of the plasma processing apparatus according to the aspect, since the voltage of the first direct-current power which is supplied from the separate direct-current power supply is stepped down in the DC/DC converter of each of the plurality of amplifier modules, the current flowing through the cable provided between the microwave generator and the direct-current power supply is reduced. Therefore, as the cable between the microwave generator and the direct-current power supply, it is possible to use a cable having a small cross-sectional area and low weight. Therefore, a cable that is easy to handle can be used as the cable between the microwave generator and the direct-current power supply.

In an exemplary embodiment, the plurality of amplifier modules are evenly arranged along a circumferential direction so as to surround the first module. According to the embodiment, a space around the first module is efficiently used as a space for disposing the plurality of amplifier modules. Therefore, the size of the microwave generator is reduced.

In an exemplary embodiment, the microwave generator of the plasma processing apparatus further includes a plurality of heat sinks for cooling the plurality of amplifier modules. The plurality of amplifier modules and the plurality of heat sinks are arranged alternately along the circumferential direction. According to the embodiment, the plurality of heat sinks are efficiently disposed in the space around the first module, in which the plurality of amplifier modules are arranged. Therefore, the microwave generator further provided with the plurality of heat sinks and having a small size is provided.

In an exemplary embodiment, the microwave generator of the plasma processing apparatus further includes a waveform generator configured to generate the high-frequency electric signal. The first module may include the waveform generator.

In an exemplary embodiment, the plasma processing apparatus further includes: a direct-current power supply and a cable. The direct-current power supply is configured to generate the first direct-current power described above. The cable is configured to transmit the first direct-current power between the direct-current power supply and the plurality of amplifier modules of the microwave generator.

In the plasma processing apparatus of the above-described embodiment, the microwave generator and the direct-current power supply are separate bodies. Therefore, the size of the microwave generator is small, and thus an area which is occupied by the microwave generator is reduced. Further, it is possible to dispose the direct-current power supply in a space (for example, a facility room) different from the space in which the microwave generator is disposed.

In an exemplary embodiment, the cable is a cabtire cable. The cable satisfies that weight thereof is 20 kg or less, an outer diameter thereof is 20 mm or less, a minimum bending radius thereof is 100 mm or less, and a withstand voltage thereof is 600 V or less. Further, the cable is a multicore cable satisfying that a total cross-sectional area of one or more conductors in the cable is 8 mm² or less. Handling of the cable having such weight, an outer diameter, a bending radius, and a withstand voltage is easy. Further, according to the multicore cable having such a cross-sectional area, a power necessary for generation of a microwave can be transmitted within an allowable current range.

In an exemplary embodiment, the plasma processing apparatus further includes: a chamber body providing a chamber; and an antenna. The antenna is connected to the microwave generator and is configured to introduce a microwave to the chamber to excite gas which is supplied to the chamber. Since the microwave generator used in the plasma processing apparatus is small, the size of the plasma processing apparatus also becomes small. Therefore, the area which is occupied by the plasma processing apparatus is reduced.

In an exemplary embodiment, the plasma processing apparatus is provided with a plurality of microwave generators, each of which is the microwave generator in the above-described aspect or any one of the various embodiments. The plasma processing apparatus further includes: a direct-current power supply and a plurality of cables. The direct-current power supply is configured to generate the first direct-current power described above. The plurality of cables transmit the first direct-current power between the direct-current power supply and the plurality of amplifier modules of the plurality of microwave generators. According to the plasma processing apparatus, direct-current power is supplied from a single direct-current power supply to the plurality of microwave generators.

In an exemplary embodiment, the plasma processing apparatus further includes: a plurality of chamber bodies; and a plurality of antennas. The plurality of antennas are connected to the plurality of microwave generators and are configured to introduce microwaves to a plurality of chambers provided by the plurality of chamber bodies, respectively, in order to excite a gas which is supplied to the plurality of chambers. In the plasma processing apparatus, the direct-current power from the single direct-current power supply is supplied to the plurality of microwave generators for the plurality of chambers.

Hereinafter, various exemplary embodiments will be described in detail with reference to the drawings. In the drawing, identical or corresponding portions are denoted by the same reference symbols.

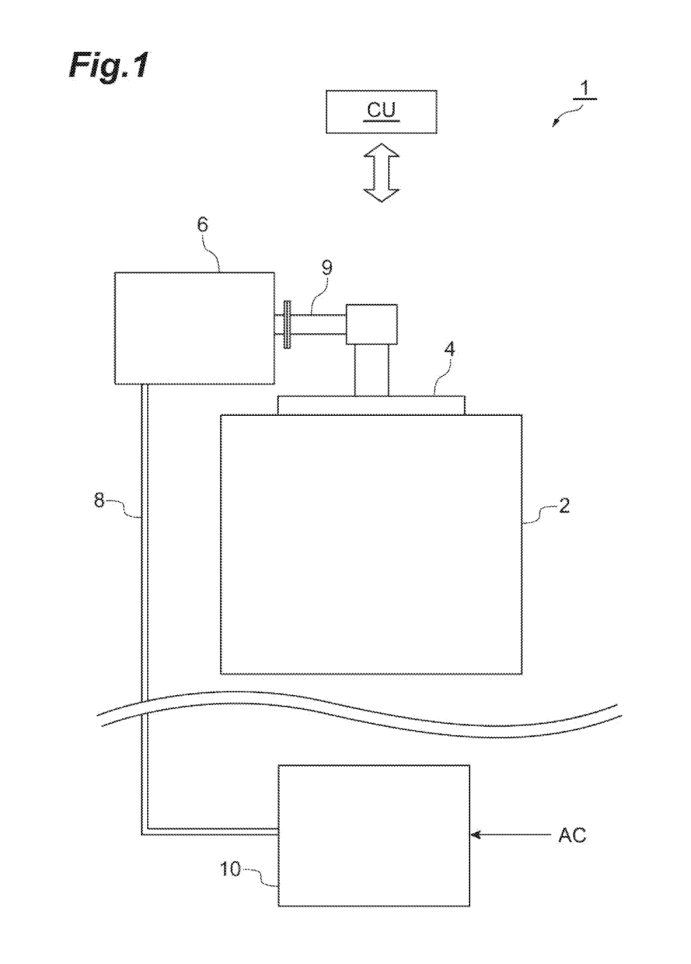

FIG. 1 is a diagram schematically illustrating a plasma processing apparatus according to an exemplary embodiment. A plasma processing apparatus 1 illustrated in FIG. 1 is provided with a chamber body 2, an antenna 4, a microwave generator 6, a cable 8, and a direct-current power supply 10. The plasma processing apparatus 1 may be further provided with a waveguide part 9. The chamber body 2, the antenna 4, the microwave generator 6, and the waveguide part 9 are disposed in, for example, a clean room. The direct-current power supply 10 is disposed in a separate room such as a facility room, for example. The microwave generator 6 and the direct-current power supply 10 are electrically connected to each other through the cable 8. In the plasma processing apparatus 1, a gas in the chamber body 2 is excited by a microwave introduced from the antenna 4. The microwave is generated by the microwave generator 6 and supplied to the antenna 4 through the waveguide part 9.

The microwave generator 6 configures a solid-state power amplifier and uses a direct-current power from the direct-current power supply 10 in power amplification for the generation of the microwave. The direct-current power is supplied from the direct-current power supply 10 to the microwave generator 6 through the cable 8. The direct-current power supply 10 is a switching power supply. The direct-current power supply 10 converts a commercial alternating-current power into a direct-current power (a first direct-current power). The direct-current power supply 10 converts, for example, an alternating-current power of 200 V into a direct-current power having a voltage of 200 V or more and 600 V or less.

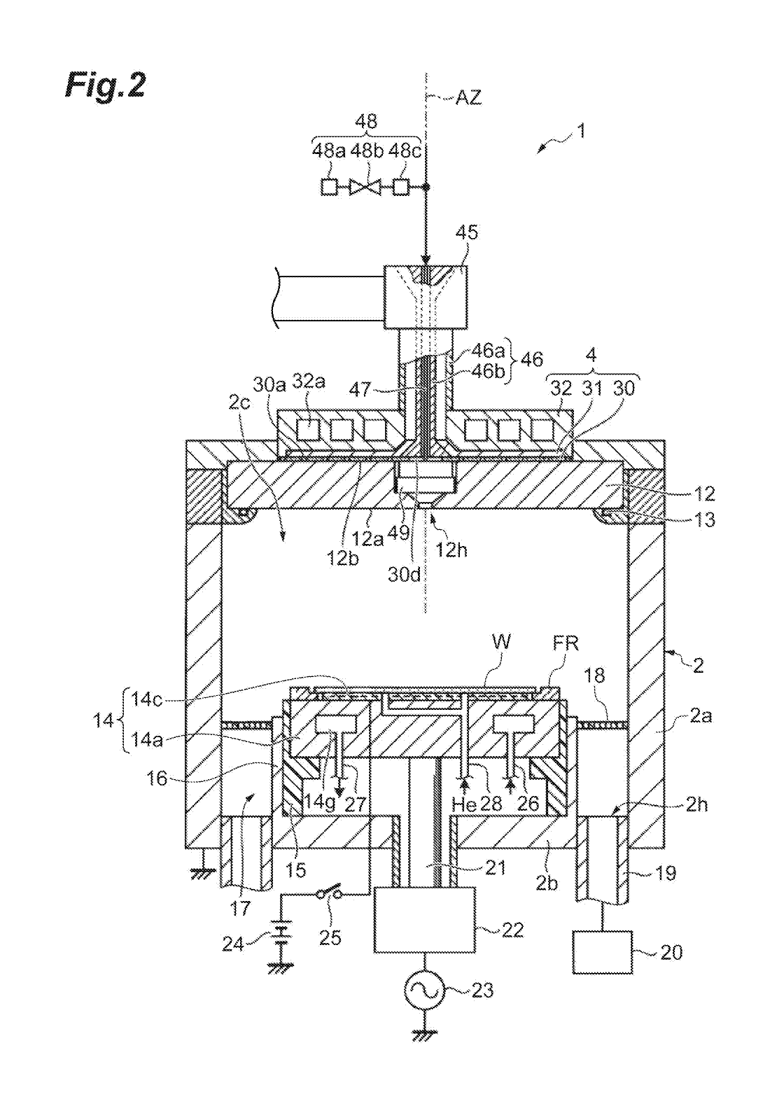

FIG. 2 is a partially broken view illustrating the plasma processing apparatus illustrated in FIG. 1. As illustrated in FIG. 2, the chamber body 2 provides an internal space thereof as a chamber 2c. The chamber body 2 has a side wall 2a and a bottom portion 2b. The side wall 2a has a substantially tubular shape. The center axis of the side wall 2a substantially coincides with an axis AZ extending in a vertical direction. The bottom portion 2b is provided on the lower end side of the side wall 2a. An exhaust hole 2h for exhaust is provided in the bottom portion 2b. Further, an opening is provided in an upper end portion of the side wall 2a.

A dielectric window 12 is provided on the upper end portion of the side wall 2a. This dielectric window is formed of a dielectric such as quartz or an aluminum oxide. The dielectric window 12 has a substantially disk shape. The dielectric window 12 has a lower surface 12a. The lower surface 12a is the surface of the dielectric window 12 on the chamber 2c side. The dielectric window 12 closes the opening of the upper end portion of the side wall 2a. An O-ring 13 is provided between the dielectric window 12 and the upper end portion of the side wall 2a. Airtightness is secured between the chamber body 2 and the dielectric window 12 by the O-ring 13.

A stage 14 is provided in the chamber 2c. The stage 14 is provided below the dielectric window 12 and faces the dielectric window 12 with a space in the chamber 2c interposed therebetween. The stage 14 is configured so as to support a workpiece W which is placed thereon. The workpiece W has a disk shape like a wafer.

The stage 14 may include a base 14a and an electrostatic chuck 14c. The base 14a has a substantially disk shape and is formed of an electrically conductive material such as aluminum. The center axis of the base 14a substantially coincides with the axis AZ. The base 14a is supported by a tubular support part 15. The tubular support part 15 is formed of an insulating material and extends upward from the bottom portion 2b. An electrically conductive tubular support part 16 is provided on the outer periphery of the tubular support part 15. The tubular support part 16 extends upward from the bottom portion 2b of the chamber body 2 along the outer periphery of the tubular support part 15. An annular exhaust path 17 is formed between the tubular support part 16 and the side wall 2a.

A baffle plate 18 is provided above the exhaust path 17. The baffle plate 18 has an annular shape. A plurality of through-holes penetrating the baffle plate 18 in a plate thickness direction thereof are formed in the baffle plate 18. The exhaust hole 2h is provided below the baffle plate 18. An exhaust device 20 is connected to the exhaust hole 2h through an exhaust pipe 19. The exhaust device 20 has an automatic pressure control valve and a vacuum pump such as a turbo molecular pump. The chamber 2c can be depressurized by the exhaust device 20.

The base 14a is used as a high-frequency electrode. A high-frequency power supply 23 for RF bias is electrically connected to the base 14a through a power supply rod 21 and a matching unit 22. The high-frequency power supply 23 outputs a high frequency wave (high-frequency energy) for bias. The high frequency wave output by the high-frequency power supply 23 has a frequency suitable for controlling the energy of ions which are attracted to the workpiece W. The frequency of the high frequency wave output by the high-frequency power supply 23 can be, for example, 13.56 MHz. The matching unit 22 has a matcher for performing matching between the impedance on the high-frequency power supply 23 side and the impedance on the load side such as mainly an electrode, plasma, and the chamber body 2. The matcher includes a blocking capacitor for self-bias generation.

The electrostatic chuck 14c is provided on the base 14a. The electrostatic chuck 14c is configured to generate an electrostatic force. The electrostatic chuck 14c attracts the workpiece W to the electrostatic chuck 14c by the electrostatic force to hold the workpiece W. The electrostatic chuck 14c has an insulating layer and a film-shaped electrode provided in the insulating layer. The electrostatic chuck 14c has a substantially disk shape. The center axis line of the electrostatic chuck 14c substantially coincides with the axis AZ. A direct-current power supply 24 is electrically connected to the electrode of the electrostatic chuck 14c through a switch 25. When direct-current voltage is applied to the electrode of the electrostatic chuck 14c by the direct-current power supply 24, the electrostatic chuck 14c generates the electrostatic force. A focus ring FR is disposed on the base 14a so as to surround the electrostatic chuck 14c and the workpiece W.

A flow path 14g is formed in the interior of the base 14a. The flow path 14g extends, for example, spirally around the axis AZ. A refrigerant from a chiller unit is supplied to the flow path 14g through a pipe 26. The refrigerant supplied to the flow path 14g is returned to the chiller unit through a pipe 27. The temperature of the refrigerant is adjusted by the chiller unit, whereby the temperature of the electrostatic chuck 14c and consequently the temperature of the workpiece W are adjusted.

Further, the plasma processing apparatus 1 is provided with a gas supply line 28. The gas supply line 28 extends to the upper surface of the electrostatic chuck 14c through the stage 14. The gas supply line 28 is provided in order to supply a heat transfer gas (for example, He gas) between the upper surface of the electrostatic chuck 14c and the back surface of the workpiece W.

As described above, the antenna 4 is provided on the dielectric window 12. That is, the antenna 4 is provided on a surface 12b of the dielectric window 12. The surface 12b is the surface on the side opposite to the lower surface 12a of the dielectric window 12. The antenna 4 is configured to introduce a microwave into the chamber 2c. In an embodiment, the antenna 4 includes a slot plate 30, a dielectric plate 31, and a cooling jacket 32.

The slot plate 30 is provided on the surface 12b of the dielectric window 12. The slot plate 30 is formed of metal having conductivity and has a substantially disk shape. The center axis of the slot plate 30 substantially coincides with the axis AZ. A plurality of slot holes 30a are formed in the slot plate 30. In an example, the plurality of slot holes 30a configure a plurality of slot pairs. Each of the plurality of slot pairs includes two slot holes 30a having substantially elongated hole shapes extending in directions intersecting each other. The plurality of slot pairs are arranged along one or more concentric circles around the axis AZ. Further, a through-hole 30d through which a conduit (described later) can pass is formed in a central portion of the slot plate 30.

The dielectric plate 31 is provided on the slot plate 30. The dielectric plate 31 is formed of a dielectric material such as quartz or an aluminum oxide and has a substantially disk shape. The center axis of the dielectric plate 31 substantially coincides with the axis AZ. The cooling jacket 32 is provided on the dielectric plate 31. The surface of the cooling jacket 32 has conductivity. The dielectric plate 31 is provided between the cooling jacket 32 and the slot plate 30 so as to provide a microwave waveguide. A flow path 32a is formed in the interior of the cooling jacket 32. A refrigerant is supplied to the flow path 32a.

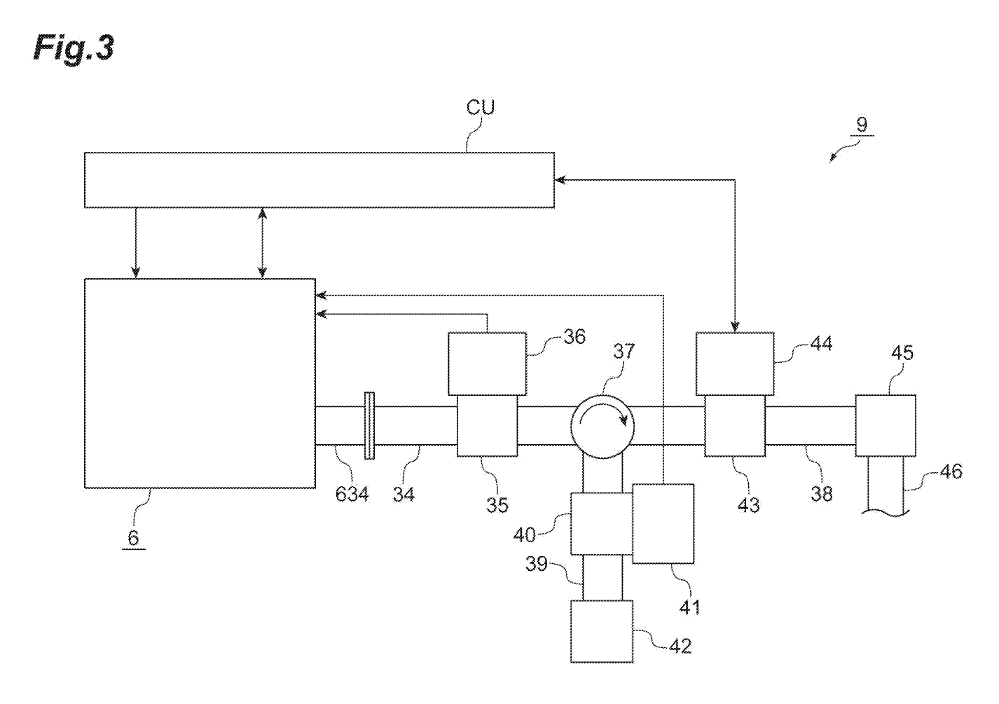

The antenna 4 is connected to the microwave generator 6 through the waveguide part 9. FIG. 3 is a diagram illustrating the waveguide part of the plasma processing apparatus illustrated in FIG. 1, together with the microwave generator and a control unit. As illustrated in FIG. 3, in an embodiment, the waveguide part 9 has a waveguide 34, a directional coupler 35, a measuring unit 36, a circulator 37, a waveguide 38, a waveguide 39, a directional coupler 40, a measuring unit 41, a load 42, a tuner 43, a tuner control unit 44, a mode converter 45, and a coaxial waveguide 46.

One end of the waveguide 34 is connected to the output of the microwave generator 6. The directional coupler 35 is provided between one end and the other end of the waveguide 34. The directional coupler 35 is configured to branch a part of a microwave (that is, a traveling wave) propagating from the one end to the other end of the waveguide 34 to output a part of the traveling wave. The measuring unit 36 is configured to measure the power of the part of the traveling wave output from the directional coupler 35 and determine the power of the traveling wave by using the value of the power of the part of the traveling wave. The measuring unit 36 outputs the determined power value of the traveling wave to a power control unit (described later) of the microwave generator 6.

The other end of the waveguide 34 is connected to a first port of the circulator 37. The circulator 37 has the first port, a second port, and a third port. The circulator 37 outputs the microwave (the traveling wave), which is input to the first port, to the second port and outputs a microwave (a reflected wave), which is input to the second port, to the third port. One end of the waveguide 38 is connected to the second port of the circulator 37. One end of the waveguide 39 is connected to the third port of the circulator 37.

The directional coupler 40 is provided between the one end and the other end of the waveguide 39. The directional coupler 40 is configured to branch a part of the microwave (the reflected wave) propagating from the one end to the other end of the waveguide 39 to output the part of the reflected wave. The measuring unit 41 is configured to measure the power of the part of the reflected wave output from the directional coupler 40 and determine the power of the reflected wave by using the value of the power of the part of the reflected wave. The measuring unit 41 outputs the determined power value of the reflected wave to the power control unit (described later) of the microwave generator 6.

The load 42 is connected to the other end of the waveguide 39. The load 42 absorbs the microwave (the reflected wave) propagating from the one end to the other end of the waveguide 39. The load 42 converts, for example, the energy of the microwave into heat.

The tuner 43 is provided between the one end and the other end of the waveguide 38. The tuner 43 has a plurality of movable parts (movable plates or movable rods). Each of the plurality of movable parts is configured such that the amount of protrusion thereof with respect to the internal space of the waveguide 38 can be adjusted. The tuner 43 matches the impedance of the microwave generator 6 with the impedance of a load on the chamber body 2 side by adjusting the positions of the plurality of movable parts with respect to the reference position. The control of the tuner 43 is executed by the tuner control unit 44. The tuner control unit 44 controls the tuner 43 in response to a control signal which is supplied from a control unit CU of the plasma processing apparatus 1.

The mode converter 45 is connected to the other end of the waveguide 38. The mode converter 45 converts the mode of the microwave which is input from the waveguide 38. One end of the coaxial waveguide 46 is connected to the mode converter 45. The microwave which has been subjected to the mode conversion by the mode converter 45 is supplied to the coaxial waveguide 46.

As illustrated in FIG. 2, the coaxial waveguide 46 includes an outer conductor 46a and an inner conductor 46b. The outer conductor 46a has a substantially cylindrical shape, and the center axis thereof substantially coincides with the axis AZ. The inner conductor 46b has a substantially cylindrical shape and extends inside the outer conductor 46a. The center axis of the inner conductor 46b substantially coincides with the axis AZ. The coaxial waveguide 46 transmits the microwave from the mode converter 45 to the antenna 4.

A lower end of the outer conductor 46a of the coaxial waveguide 46 is electrically connected to the upper surface of the cooling jacket 32 described above. Further, a lower end portion of the inner conductor 46b is electrically connected to the slot plate 30 through holes formed in the central portions of the cooling jacket 32 and the dielectric plate 31. The microwave from the coaxial waveguide 46 propagates through the dielectric plate 31 and is supplied from the plurality of slot holes 30a of the slot plate 30 to the dielectric window 12. The microwave supplied to the dielectric window 12 is introduced into the chamber 2c.

A conduit 47 passes through an inner hole of the inner conductor 46b of the coaxial waveguide 46. As described above, the through-hole 30d through which the conduit 47 can pass is formed in the central portion of the slot plate 30. The conduit 47 extends through the inner hole of the inner conductor 46b and is connected to a gas supply system 48.

The gas supply system 48 supplies a gas for processing the workpiece W to the conduit 47. The gas supply system 48 may include one or more gas sources 48a, one or more on-off valves 48b, and one or more flow rate controllers 48c. The one or more on-off valves 48b switch the supply and the stop of the supply of the gas from one or more gas sources 48a. The one or more flow rate controllers 48c are, for example, mass flow controllers and adjust the flow rate of the gas from one or more gas sources 48a.

The plasma processing apparatus 1 may be further provided with an injector 49. The injector 49 supplies the gas from the conduit 47 to a through-hole 12h formed in the dielectric window 12. The gas supplied to the through-hole 12h of the dielectric window 12 is supplied to the chamber 2c. Then, the gas is excited by the microwave introduced from the dielectric window 12 into the chamber 2c. In this way, a plasma is generated in the chamber 2c, and the workpiece W is processed by active species such as ions and/or radicals from the plasma.

As illustrated in FIG. 1, the plasma processing apparatus 1 can be further provided with the control unit CU. The control unit CU collectively controls the respective parts of the plasma processing apparatus 1. The control unit CU may be provided with a processor such as a CPU, a user interface, and a storage unit.

The processor collectively controls the respective parts such as the microwave generator 6, the tuner control unit 44, the exhaust device 20, the matching unit 22, the high-frequency power supply 23, the switch 25, and the gas supply system 48 by executing a program and a process recipe stored in the storage unit.

The user interface includes a keyboard or a touch panel through which an operator performs a command input operation or the like in order to manage the plasma processing apparatus 1, a display for visualizing and displaying the operational status or the like of the plasma processing apparatus 1, and the like.

A control program (software) for realizing a variety of processing which are executed in the plasma processing apparatus 1, by the control of the processor, a process recipe which includes processing condition data or the like, and the like are stored in the storage unit. The processor calls various control programs from the storage unit and executes them as necessary such as according to the instructions from the user interface. Under such control of the processor, desired processing is executed in the plasma processing apparatus 1.

Hereinafter, the microwave generator 6 will be described in detail. The microwave generator 6 outputs the microwaves for exciting the gas in the chamber 2c. The microwave generator 6 is configured to variably adjust the frequency, a power, and a bandwidth of the microwave. The microwave generator 6 can generate a microwave having a single frequency, for example, by setting the bandwidth of the microwave to approximately zero. Further, the microwave generator 6 can generate a microwave which includes a plurality of frequency components within the bandwidth thereof. The power of the plurality of frequency components may be the same power, or only the center frequency component in the band may have a power higher than the power of the other frequency components.

In an example, the microwave generator 6 can adjust the power of the microwave within a range of 0 W to the maximum output power. The maximum output power can be, for example, a power of 6000 W or more. Further, the microwave generator 6 can adjust the frequency or the center frequency of the microwave within a range of 2400 MHz to 2500 MHz and adjust the bandwidth of the microwave in a range of 0 to 100 MHz. Further, the microwave generator 6 can adjust the pitch (carrier pitch) of frequencies of a plurality of frequency components of the microwave in the band within a range of 0 to 25 kHz.

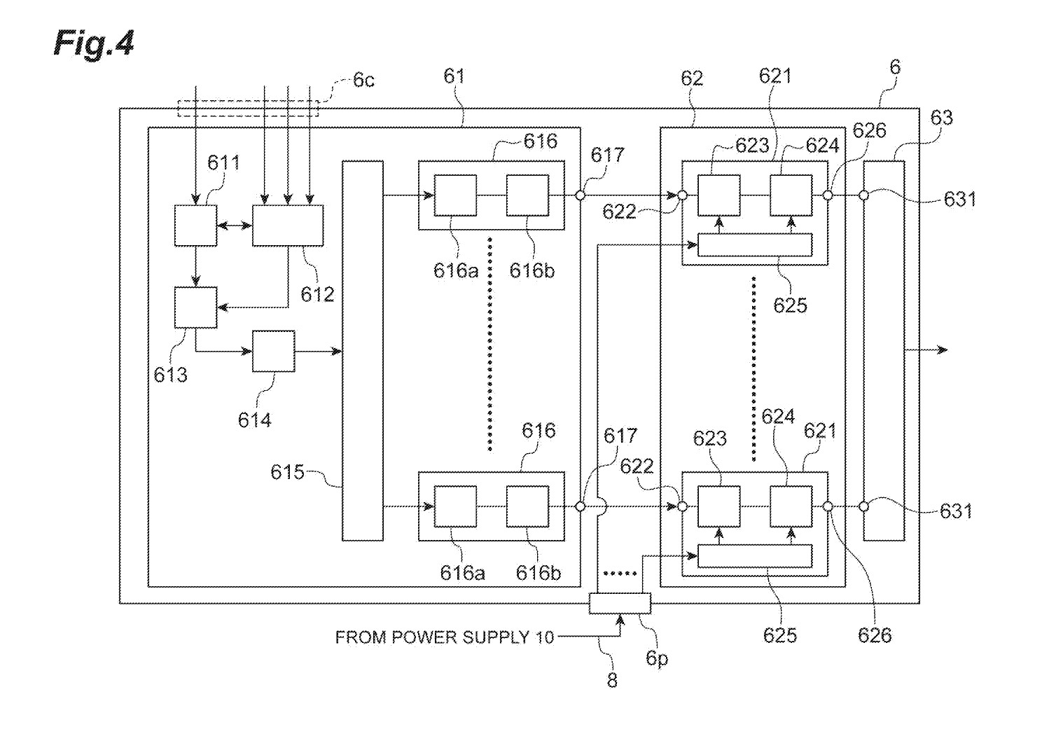

FIG. 4 is a diagram illustrating a configuration of the microwave generator of the plasma processing apparatus illustrated in FIG. 1. As illustrated in FIG. 4, the microwave generator 6 is provided with a first module 61, a second module 62, and a combiner 63. The first module 61 includes a distributor 615 configured to distribute a high-frequency electric signal, and is configured to output a plurality of high-frequency electric signals. In an embodiment, the first module 61 may further include a waveform generator 611, a power control unit 612, an attenuator 613, an amplifier 614, and an adjustment unit 616. The waveform generator 611 may be provided outside the first module 61.

The waveform generator 611 is connected to the control unit CU through a control terminal 6c. Further, the waveform generator 611 is connected to the power control unit 612. The power control unit 612 is connected to the control unit CU, the measuring unit 36, and the measuring unit 41 through the control terminal 6c. The waveform generator 611 generates a high-frequency electric signal having a frequency (or a center frequency), a bandwidth, and a carrier pitch respectively corresponding to a set frequency, a set bandwidth, and a set pitch which are designated by the control signal from the control unit CU. In a case where the control unit CU designates the power of a plurality of frequency components in the band through the power control unit 612, the waveform generator 611 may generate a high-frequency electric signal which includes a plurality of frequency components each having power reflecting the power of the plurality of frequency components designated by the control unit CU.

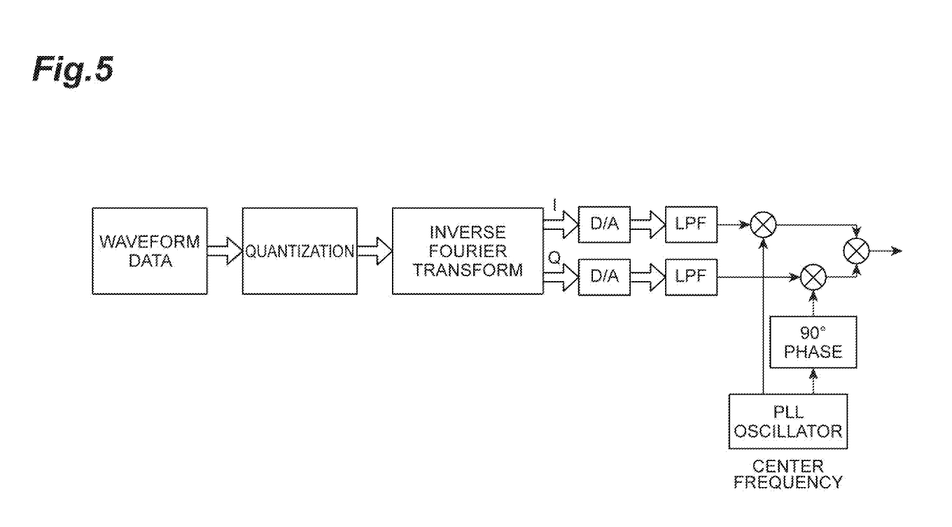

FIG. 5 is a diagram for explaining the principle of generation of a high-frequency electric signal in the waveform generator illustrated in FIG. 4. The waveform generator 611 has, for example, a PLL (Phase Locked Loop) oscillator and an IQ digital modulator connected to the PLL oscillator. The PLL oscillator oscillates a high-frequency electric signal having a phase synchronized with that of the reference frequency. The waveform generator 611 sets the frequency of the high-frequency electric signal which is oscillated in the PLL oscillator to the set frequency designated by the control unit CU. Then, the waveform generator 611 modulates the high-frequency electric signal from the PLL oscillator and a high-frequency electric signal having a phase difference of 90° with respect to the high-frequency electric signal from the PLL oscillator by using the IQ digital modulator. In this way, the waveform generator 611 generates a high-frequency electric signal which includes a plurality of frequency components in the band, or a high-frequency electric signal having a single frequency.

As illustrated in FIG. 5, the waveform generator 611 generates a high-frequency electric signal which includes a plurality of frequency components, for example, by generating a continuous signal by performing an inverse discrete Fourier transform on N complex data symbols. This signal generation method can be the same method as a OFDMA (Orthogonal Frequency-Division Multiple Access) modulation method which is used in digital television broadcasting or the like (refer to, for example, Japanese Patent No. 5320260).

In an example, the waveform generator 611 has waveform data represented by a sequence of digitized codes in advance. The waveform generator 611 generates I data and Q data by quantizing the waveform data and applying inverse Fourier transform to the quantized data. Then, the waveform generator 611 obtains two analog signals by applying D/A (Digital/Analog) conversion to each of the I data and the Q data. The waveform generator 611 inputs these analog signals to an LPF (low-pass filter) which passes only a low frequency component. The waveform generator 611 mixes each of the two analog signals output from the LPF with each of the high-frequency electric signal from the PLL oscillator and the high-frequency electric signal having the phase difference of 90° with respect to the high-frequency electric signal from the PLL oscillator, respectively. Then, the waveform generator 611 combines the high-frequency electric signals generated by the mixing. In this way, the waveform generator 611 generates a high-frequency electric signal which includes one or a plurality of frequency components.

The output of the waveform generator 611 is connected to the attenuator 613. The power control unit 612 is connected to the attenuator 613. The power control unit 612 may be, for example, a processor. The power control unit 612 controls an attenuation rate of a high-frequency electric signal in the attenuator 613 such that a microwave having power corresponding to the set power designated from the control unit CU is output from the microwave generator 6. Further, the power control unit 612 receives the value of the power of the traveling wave from the measuring unit 36 through the control terminal 6c and receives the value of the power of the reflected wave from the measuring unit 41. The power control unit 612 controls the attenuator 613 such that the difference between the value of the power of the traveling wave and the value of the power of the reflected wave, that is, load power, coincides with the set power which is designated by the control unit CU, and controls the waveform generator 611, as necessary.

The output of the attenuator 613 is connected to the distributor 615 through the amplifier 614. The amplifier 614 is configured to amplify the high-frequency electric signal received from the attenuator 613 with a predetermined amplification factor to output the amplified high-frequency electric signal. The distributor 615 distributes the high-frequency electric signal output from the amplifier 614 to output a plurality of high-frequency electric signals from a plurality of outputs thereof, respectively. The plurality of outputs of the distributor 615 are respectively connected to a plurality of adjustment units 616.

Each of the plurality of adjustment units 616 has an amplitude/phase adjusting unit 616a and a pre-driver amplifier 616b. The amplitude/phase adjusting unit 616a includes, for example, a variable attenuator and a phase shifter and adjusts the amplitude and the phase of the input high-frequency electric signal. The amplitude/phase adjusting unit 616a outputs the high-frequency electric signal having the adjusted amplitude and phase to the pre-driver amplifier 616b. The pre-driver amplifier 616b amplifies the input high-frequency electric signal. The pre-driver amplifier 616b outputs the amplified high-frequency electric signal. The amplitude adjustment amount and the phase adjustment amount in each of the plurality of adjustment units 616 can be adjusted individually. The amplitude adjustment amount and the phase adjustment amount in each of the plurality of adjustment units 616 are adjusted such that the amplitudes and the phases of the high-frequency electric signals which are output from these adjustment units 616 become equal to each other. The first module 61 has a plurality of output terminals 617. The outputs of the pre-driver amplifiers 616b of the plurality of adjustment units 616 are respectively connected to the plurality of output terminals 617.

The second module 62 is provided with a plurality of amplifier modules 621. The number of the plurality of amplifier modules 621 is the same as the number of the plurality of output terminals 617 of the first module 61, that is, the number of the plurality of high-frequency electric signals which are output from the first module 61. In an embodiment, the number of the plurality of amplifier modules 621 is the number which is equal to or larger than the value which is obtained by adding one to the quotient which is obtained by dividing the maximum output power in the specification of the microwave generator 6 by the average value of the output power at the maximum operating points of the plurality of amplifier modules 621. Although the number of the plurality of amplifier modules 621 is sixteen in the illustrated example, it may be an arbitrary number. Each of the plurality of amplifier modules 621 has an input terminal 622, an amplifier 623, an amplifier 624, a DC/DC converter 625, and an output terminal 626.

The input terminal 622 of each of the plurality of amplifier modules 621 is connected to the corresponding output terminal 617 among the plurality of output terminals 617 of the first module 61. In each of the plurality of amplifier modules 621, the input terminal 622 is connected to the input of the amplifier 623. The amplifier 623 is an amplifier which includes a semiconductor element, and is a driver amplifier. The output of the amplifier 623 is connected to the input of the amplifier 624. The amplifier 624 is an amplifier which includes a semiconductor element, and is a final amplifier. The output of the amplifier 624 is connected to the output terminal 626. Each of the plurality of amplifier modules 621 generates a microwave by amplifying the high-frequency electric signal received from the corresponding output terminal 617 of the first module 61 by the amplifier 623 and the amplifier 624. The generated microwave is output from the output terminal 626.

The amplifier 623 and the amplifier 624 of each of the plurality of amplifier modules 621 amplify the high-frequency electric signal by using the direct-current power (second direct-current power) which is provided from the DC/DC converter 625. The direct-current power supply 10 is connected to a terminal 6p of the microwave generator 6 through the cable 8. The terminal 6p and the DC/DC converters 625 of the plurality of amplifier modules 621 are connected by a plurality of wires. The direct-current power (first direct-current power) from the direct-current power supply 10 is supplied to the DC/DC converter 625 of each of the plurality of amplifier modules 621. In each of the plurality of amplifier modules 621, the DC/DC converter 625 steps down the voltage of the direct-current power (first direct-current power) from the direct-current power supply 10 to a voltage suitable for the driving of the amplifier 623 and the amplifier 624. Each of the plurality of amplifier modules 621 steps down the voltage of the direct-current power from the direct-current power supply 10 to, for example, 30 V. In each of the plurality of amplifier modules 621, the direct-current power (second direct-current power) having a voltage stepped down by the DC/DC converter 625 is provided to the amplifier 623 and the amplifier 624.

The combiner 63 has a plurality of input terminals 631. The output terminals 626 of the plurality of amplifier modules 621 are respectively connected to the plurality of input terminals 631 of the combiner 63. The combiner 63 combines the plurality of microwaves respectively input to the plurality of input terminals 631 by spatial combining to output a microwave. The output of the combiner 63, that is, the output of the microwave generator 6, is connected to the one end of the waveguide 34.

In order to amplify a high-frequency electric signal in an amplifier, a direct-current power having a voltage suitable for the driving of the amplifier must be provided to the amplifier. One measure for obtaining such a direct-current power is to integrate a switching power supply with a microwave generator. The switching power supply is a switching power supply which converts commercial alternating-current power into a direct-current power having a voltage suitable for the driving of an amplifier. A microwave generator integrated with such a switching power supply becomes large in both the size and the weight thereof. Another measure is to provide a switching power supply which converts commercial alternating-current power into direct-current power having a voltage suitable for the driving of an amplifier as a separate body from a microwave generator and connect the switching power supply and the microwave generator by a cable for power transmission. However, in this measure, since a current flowing through the cable becomes large, the cross-sectional area of the cable becomes large and the weight of the cable becomes heavy. Therefore, handling of the cable is not easy.

On the other hand, in the microwave generator 6, each of the amplifier modules 621 has the DC/DC converter 625 and the amplifiers 623 and 624. The DC/DC converter 625 receives the first direct-current power from the direct-current power supply 10, that is, the switching power supply for converting commercial alternating-current power into direct-current power, and provides the second direct-current power obtained by stepping down the voltage of the first direct-current power to the amplifiers 623 and 624. That is, the microwave generator 6 converts the first direct-current power from a separate direct-current power supply (switching power supply) into a low-voltage direct-current power in the DC/DC converter 625 of each of the amplifier modules 621 and uses the direct-current power in the amplifiers 623 and 624. Therefore, the microwave generator 6 becomes small in both the size and the weight thereof.

Further, in the microwave generator 6, since the voltage of the first direct-current power which is supplied from the separate direct-current power supply 10 is stepped down in the DC/DC converter 625 of each of the plurality of amplifier modules 621, the current flowing through the cable 8 provided between the microwave generator 6 and the direct-current power supply 10 is reduced. Therefore, as the cable 8 between the microwave generator 6 and the direct-current power supply 10, it is possible to use a cable having a small cross-sectional area and low weight. Therefore, a cable that is easy to handle can be used as the cable 8 between the microwave generator 6 and the direct-current power supply 10.

In an embodiment, the cable 8 satisfies the first condition that the weight thereof is 20 kg or less, the outer diameter thereof is 20 mm or less, the minimum bending radius thereof is 100 mm or less, and the withstand voltage thereof is 600 V or less. A general semiconductor processing apparatus is disposed across a clean room in which process processing is performed and an auxiliary machinery area having low cleanness. That is, constituent elements of the semiconductor processing apparatus, which should be disposed in a place where cleanness is required, are disposed in the clean room, and other constituent elements of the semiconductor processing apparatus are disposed in the auxiliary machinery area. Then, it is necessary to satisfy the condition that the length of a cable connecting the constituent element disposed in the clean room and the constituent element disposed in the auxiliary machinery area is 30 m or less. Therefore, in the first condition, the weight of the cable can be 20 kg or less per 30 m. Handling of the cable 8 satisfying the first condition is easy. Therefore, work of laying the cable 8 is easy.

Further, in an embodiment, the cable 8 is a multicore cable further satisfying the second condition that the total cross-sectional area of one or more conductors in the cable is 8 mm² or less. In the case where the multicore cable further satisfying the second condition is used as the cable 8, it is possible to transmit the power necessary for the generation of a microwave within an allowable current range of the cable 8. For example, assuming that the power of the microwave to be supplied to the chamber 2c is 3000 W and the conversion efficiency from the direct-current power to the power of the microwave is 50%, a direct-current power of 6000 W needs to be supplied to the microwave generator 6. Assuming that the voltage of the direct-current power which is provided from the direct-current power supply 10 to the microwave generator 6 is 200 V, the allowable current of the cable 8 needs to be 30 A or more. According to a cabtire cable, for example, a rubber cabtire cable, which is a multicore cable in which the total cross-sectional area of one or more conductors is 8 mm² or less, it is possible to obtain the cable 8 satisfying the first condition and having such an allowable current. For example, (1) a rubber cabtire cable in which the number of conductors (the number of cores) is six, the number of pairs is three, and the total cross-sectional area of the six conductors is 2 mm², (2) a rubber cabtire cable in which the number of conductors (the number of cores) is eight, the number of pairs is four, and the total cross-sectional area of the eight conductors is 2 mm², (3) a rubber cabtire cable in which the number of conductors (the number of cores) is four, the number of pairs is two, and the total cross-sectional area of the four conductors is 3.5 mm², (4) a rubber cabtire cable in which the number of conductors (the number of cores) is two, the number of pairs is one, and the total cross-sectional area of the two conductors is 5.5 mm², (5) a rubber cabtire cable in which the number of conductors (the number of cores) is four, the number of pairs is two, and the total cross-sectional area of the four conductors is 5.5 mm², or (6) a rubber cabtire cable in which the number of conductors (the number of cores) is two, the number of pairs is one, and the total cross-sectional area of the two conductors is 8 mm² can be used as the cable 8 satisfying the above conditions. The cable 8 may further satisfy the condition that a voltage drop rate per 30 m is 1% or less.

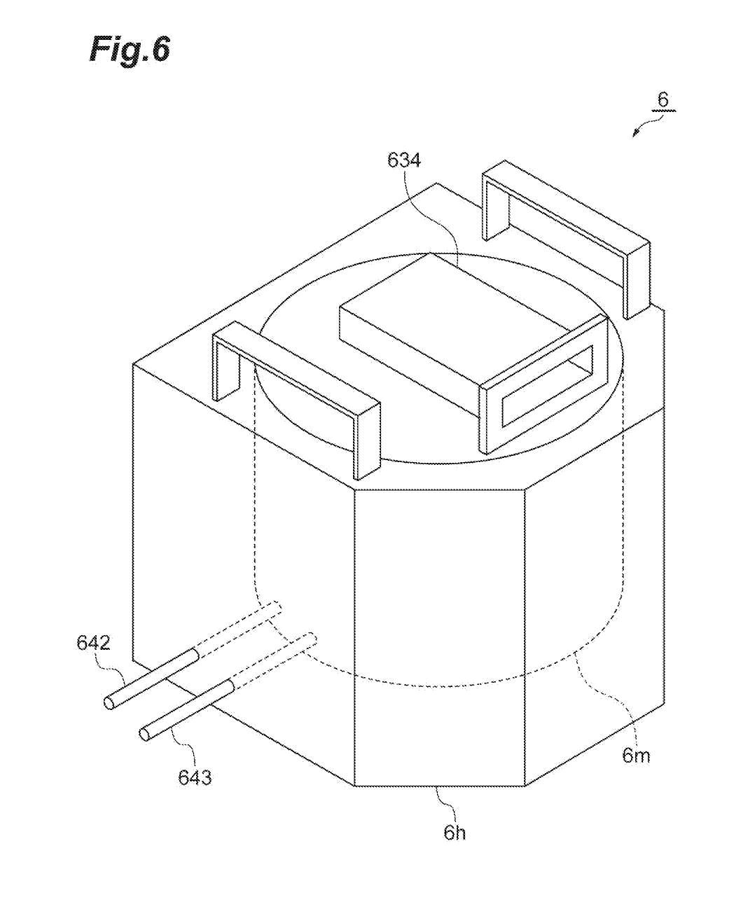

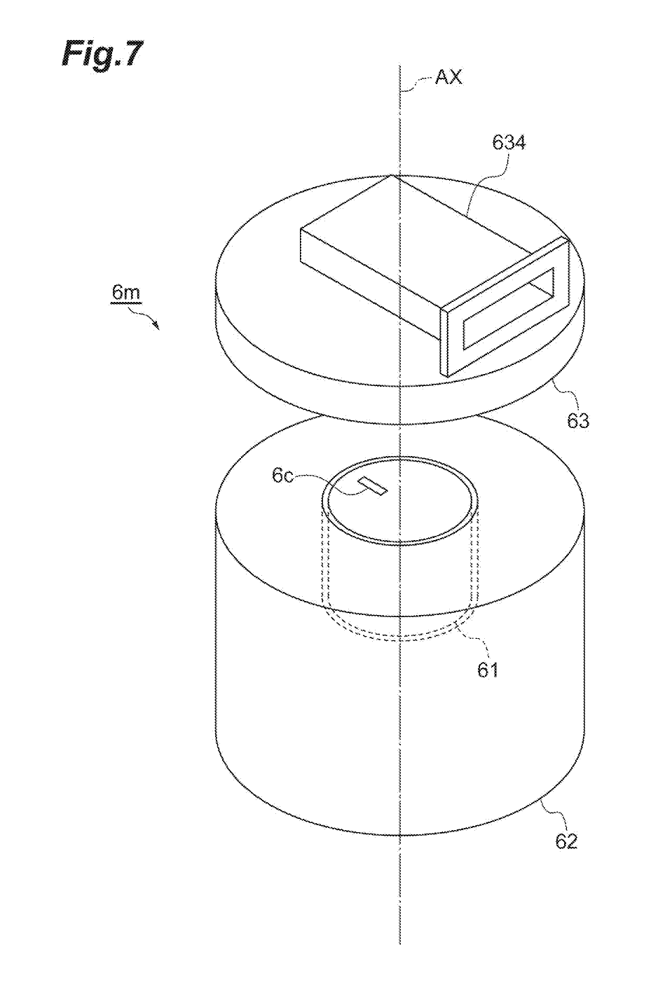

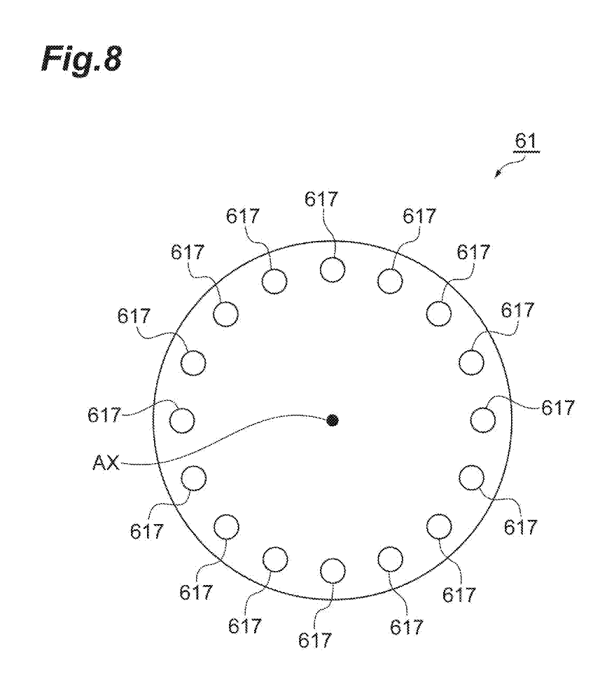

Hereinafter, the structure of the microwave generator 6 will be described. FIG. 6 is a perspective view of the microwave generator according to an exemplary embodiment. FIG. 7 is an exploded perspective view of a main unit of the microwave generator illustrated in FIG. 6. FIG. 8 is a plan view illustrating the bottom surface side of the first module of the microwave generator illustrated in FIG. 6.

As illustrated in FIG. 6, the microwave generator 6 is provided with a housing 6h and a main unit 6m. Further, the microwave generator 6 can be further provided with a pipe 642 and a pipe 643. The pipe 642 extends from the inside to the outside of the housing 6h. The pipe 642 is a pipe for supplying a refrigerant (for example, cooling water) for cooling the plurality of amplifier modules 621 of the microwave generator 6 from the outside to the inside of the housing 6h. The pipe 643 extends from the inside to the outside of the housing 6h. The pipe 643 is a pipe for discharging the refrigerant from the inside to the outside of the housing 6h. Details of the structure related to the supply and the discharge of the refrigerant will be described later.

As illustrated in FIG. 7, the main unit 6m is provided with the first module 61, the second module 62, and the combiner 63. The first module 61 is formed in a substantially columnar shape. The second module 62 is formed in a substantially cylindrical shape so as to provide a substantially columnar space inside thereof. The first module 61 is disposed in the space which is provided by the second module 62. The combiner 63 is disposed on the first module 61 and the second module 62.

The first module 61 provides the control terminal 6c. The control terminal 6c is provided on the upper surface side of the first module 61, that is, the side of the surface facing the combiner 63. As illustrated in FIG. 8, the plurality of output terminals 617 of the first module 61 are provided on the bottom surface side of the first module 61. The plurality of output terminals 617 are arranged along the circumferential direction with respect to the axis AX and are evenly arranged around the axis AX. The axis AX is a center axis which is shared by the first module 61, the second module 62, and the combiner 63. As described above, the plurality of high-frequency electric signals are output from the plurality of output terminals 617 to the second module 62.

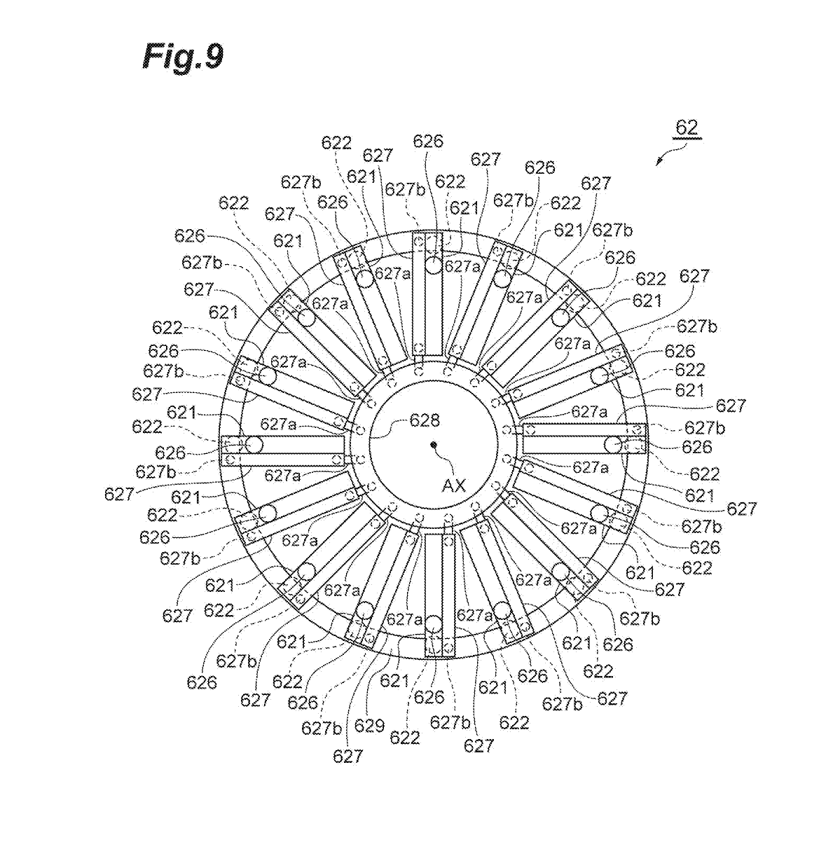

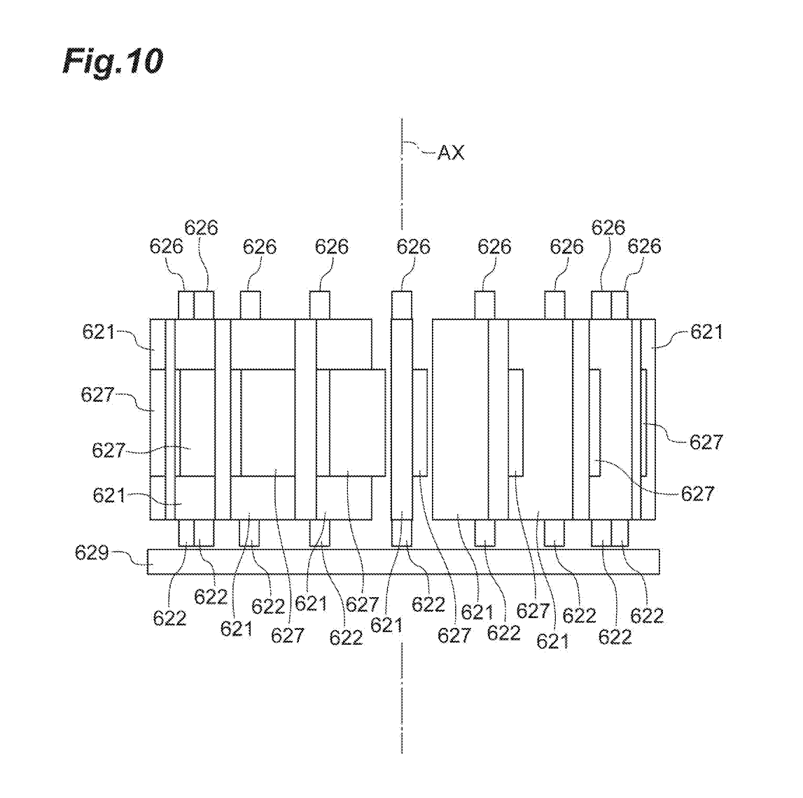

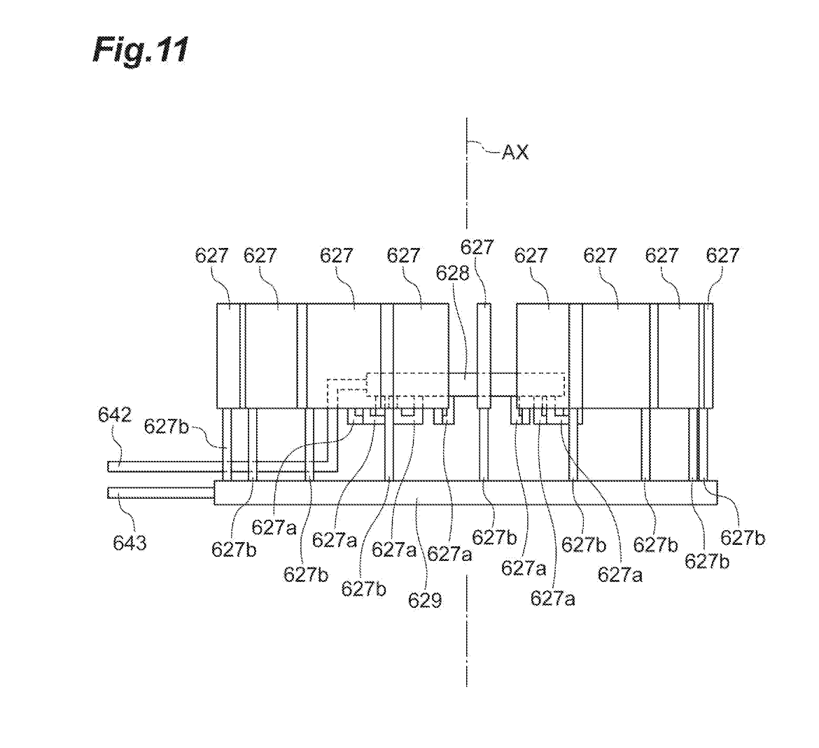

FIG. 9 is a plan view of the second module of the microwave generator illustrated in FIG. 6. FIG. 10 is a side view of the second module of the microwave generator illustrated in FIG. 6. FIG. 11 is a side view illustrating the cooling structure of the second module of the microwave generator illustrated in FIG. 6. As illustrated in FIGS. 9 and 10, the plurality of amplifier modules 621 of the second module 62 are arranged along the circumferential direction with respect to the axis AX so as to provide the space in which the first module 61 is disposed. Further, the plurality of amplifier modules 621 are evenly arranged around the axis AX.

Each of the plurality of amplifier modules 621 is formed in a substantially rectangular parallelepiped shape. That is, each of the plurality of amplifier modules 621 has a pair of side surfaces extending in a longitudinal direction and a short side direction orthogonal to the longitudinal direction. The distance between the pair of side surfaces of each of the plurality of amplifier modules 621 is shorter than the length in the longitudinal direction and the length in the short side direction. The longitudinal direction of each of the plurality of amplifier modules 621 is substantially parallel to the axis AX. Further, the short side direction of each of the plurality of amplifier modules 621 is a direction substantially orthogonal to the axis AX. That is, the short side direction of each of the plurality of amplifier modules 621 substantially coincides with a radial direction with respect to the axis AX. The length in the short side direction of each of the plurality of amplifier modules 621 is shorter than the distance between the outer periphery of the second module 62 and the axis AX, that is, the radius of the second module 62. With such disposition of the plurality of amplifier modules 621, the second module 62 defines the space in which the first module 61 is disposed.

Each of the plurality of amplifier modules 621 provides the output terminal 626 on the upper surface thereof, that is, on the side of the surface on the side facing the combiner 63. The plurality of output terminals 626 which are provided by the plurality of amplifier modules 621 are arranged along the circumferential direction with respect to the axis AX and are evenly arranged around the axis AX. The plurality of output terminals 626 are respectively connected to the plurality of input terminals 631 of the combiner 63. For example, the plurality of output terminals 626 are directly connected to the plurality of input terminals 631 of the combiner 63, respectively.

Further, each of the plurality of amplifier modules 621 provides the input terminal 622 on the lower surface on the side opposite to the upper surface thereof. The plurality of input terminals 622 which are provided by the plurality of amplifier modules 621 are respectively connected to the plurality of output terminals 617 of the first module 61 through, for example, a cable.

As illustrated in FIGS. 9 to 11, the second module 62 can be further provided with a plurality of heat sinks 627. The plurality of heat sinks 627 are elements for cooling the plurality of amplifier modules 621, respectively. A space into which the refrigerant is supplied is formed in the interior of each of the plurality of heat sinks 627. Each of the plurality of heat sinks 627 is, for example, a water-cooled heat sink. The plurality of heat sinks 627 are arranged alternately with the plurality of amplifier modules 621 along the circumferential direction. Each of the plurality of heat sinks 627 is disposed so as to be in contact with one of a pair of side surfaces of one amplifier module 621 adjacent thereto, among the plurality of amplifier modules 621. Each of the plurality of heat sinks 627 has, for example, a substantially rectangular parallelepiped shape.

The second module 62 can be further provided with a pipe 628 and a pipe 629. The pipe 628 is an annular pipe extending around the axis AX. The pipe 628 has an outer diameter smaller than the diameter of the above-described space which is provided by the second module 62, and is disposed in the space. The pipe 628 is disposed below the first module 61. One end of the pipe 642 described above is connected to the pipe 628. Further, a plurality of openings are formed in the pipe 628, and the plurality of openings are arranged in the circumferential direction with respect to the axis AX and are evenly arranged over the entire circumference of the pipe 628. One ends of a plurality of pipes 627a are connected to the plurality of openings of the pipe 628, respectively. The other ends of the plurality of pipes 627a are respectively connected to a plurality of first openings respectively provided in the bottom of the plurality of heat sinks 627. The refrigerant which is supplied from the pipe 642 to the pipe 628 is supplied to the plurality of heat sinks 627 through the plurality of pipes 627a, respectively. In this way, the refrigerant can be substantially equally supplied to the plurality of heat sinks 627.

The pipe 629 is an annular pipe extending around the axis AX. The pipe 629 may have an outer diameter larger than the outer diameter of the pipe 628. The pipe 629 is provided below the plurality of amplifier modules 621. One end of the pipe 643 described above is connected to the pipe 629. Further, a plurality of openings are formed in the pipe 629, and the plurality of openings are arranged in the circumferential direction with respect to the axis AX and are evenly arranged over the entire circumference of the pipe 629. One ends of a plurality of pipes 627b are connected to the plurality of openings of the pipe 629, respectively. The other ends of the plurality of pipes 627b are respectively connected to a plurality of second openings respectively provided in the bottom of the plurality of heat sinks 627. The refrigerant is discharged from the plurality of heat sinks 627 to the pipe 643 through the plurality of pipes 627b and the pipe 629. In this way, the refrigerant can be likewise discharged from the plurality of heat sinks 627.

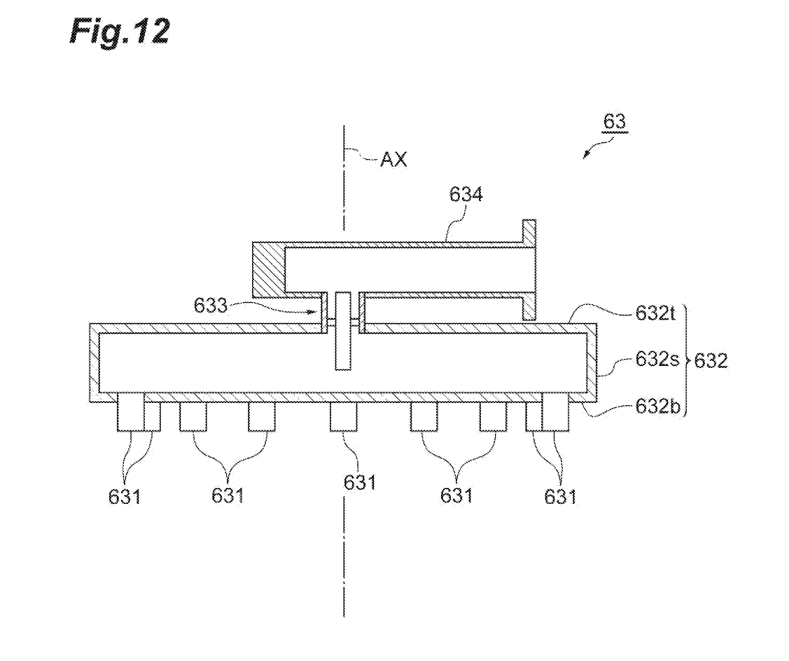

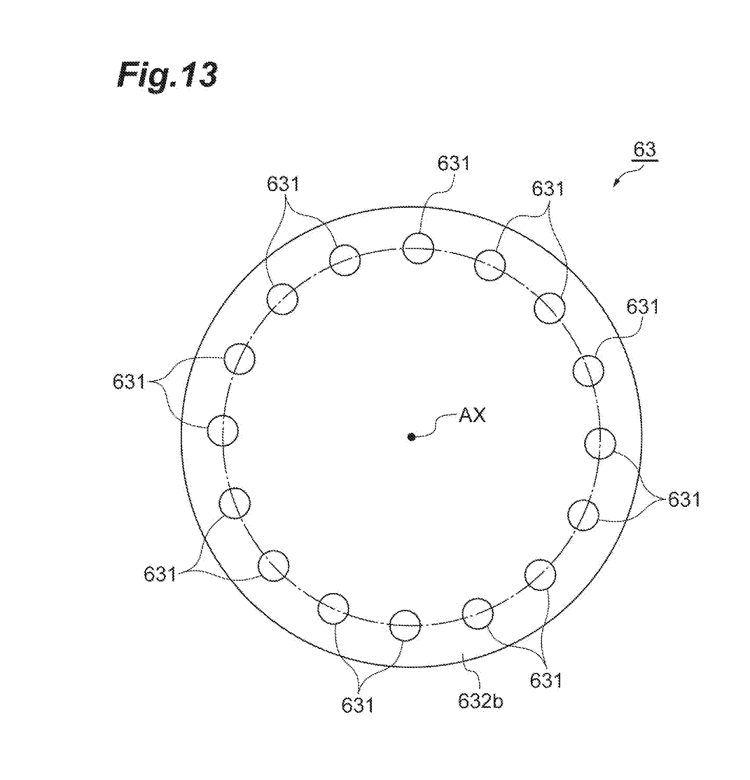

Hereinafter, FIG. 7 is referred to again. Further, FIGS. 12 and 13 are referred to along with FIG. 7. FIG. 12 is a sectional view illustrating the combiner of the main unit illustrated in FIG. 7. FIG. 13 is a plan view illustrating the combiner of the main unit illustrated in FIG. 7. The combiner 63 is configured to combine a plurality of microwaves from the plurality of amplifier modules 621 to output a microwave. The combiner 63 has the plurality of input terminals 631 and a main body 632. The combiner 63 may further have a mode converter 633 and a waveguide 634.

The main body 632 of the combiner 63 is formed in a cylindrical shape. The center axis of the main body 632 substantially coincides with the axis AX. The main body 632 defines a substantially disk-shaped internal space. The center axis of the internal space of the main body 632 substantially coincides with the axis AX. The main body 632 has a side wall 632s, an upper wall 632t, and a lower wall 632b. The side wall 632s has a cylindrical shape, and the center axis thereof substantially coincides with the axis AX.

The lower wall 632b is continuous with a lower end of the side wall 632s and extends in a direction substantially orthogonal to the axis AX. One ends of the plurality of input terminals 631 are respectively formed in a plurality of openings formed in the lower wall 632b. The plurality of input terminals 631 extend below the lower wall 632b and to the outside of the main body 632. The plurality of input terminals 631 are arranged in the circumferential direction with respect to the axis AX and are evenly arranged around the axis AX. The distance between each of the plurality of input terminals 631 and the axis AX is substantially equal to the distance between each of the plurality of output terminals 626 and the axis AX. Therefore, in a state where the combiner 63 is mounted on the second module 62, the plurality of input terminals 631 of the combiner 63 face the plurality of output terminals 626. The plurality of input terminals 631 of the combiner 63 are directly connected to the plurality of output terminals 626, respectively.

The upper wall 632t is continuous with an upper end of the side wall 632s and extends in a direction substantially orthogonal to the axis AX. The upper wall 632t provides an opening in a central portion thereof, that is, a portion substantially orthogonal to the axis AX. The mode converter 633 is mounted on the central portion of the upper wall 632t. The plurality of microwaves introduced from the plurality of input terminals 631 into the internal space of the main body 632 are combined in the main body 632. The microwave generated by combining of the plurality of microwaves in the main body 632 is input to the mode converter 633. The mode converter 633 converts the mode of the input microwave to output the microwave to the waveguide 634. The waveguide 634 is provided on the mode converter 633. The waveguide 634 is, for example, a rectangular waveguide and extends in a direction orthogonal to the axis AX. The waveguide 634 configures the output of the microwave generator 6 and is connected to the input of the waveguide part 9, that is, the one end of the waveguide 34.

In the microwave generator 6 described above, a space around the first module 61 is efficiently used as a space for disposing the plurality of amplifier modules 621. Therefore, the size of the microwave generator 6 is reduced.

In addition, the plurality of heat sinks 627 are efficiently disposed in the space around the first module 61 in which the plurality of amplifier modules 621 are arranged. Therefore, the microwave generator 6 further provided with the plurality of heat sinks 627 and having a small size is provided.

In addition, since the microwave generator 6 used in the plasma processing apparatus 1 is small, the size of the plasma processing apparatus 1 also becomes small. Therefore, an area which is occupied by the plasma processing apparatus 1 is reduced.

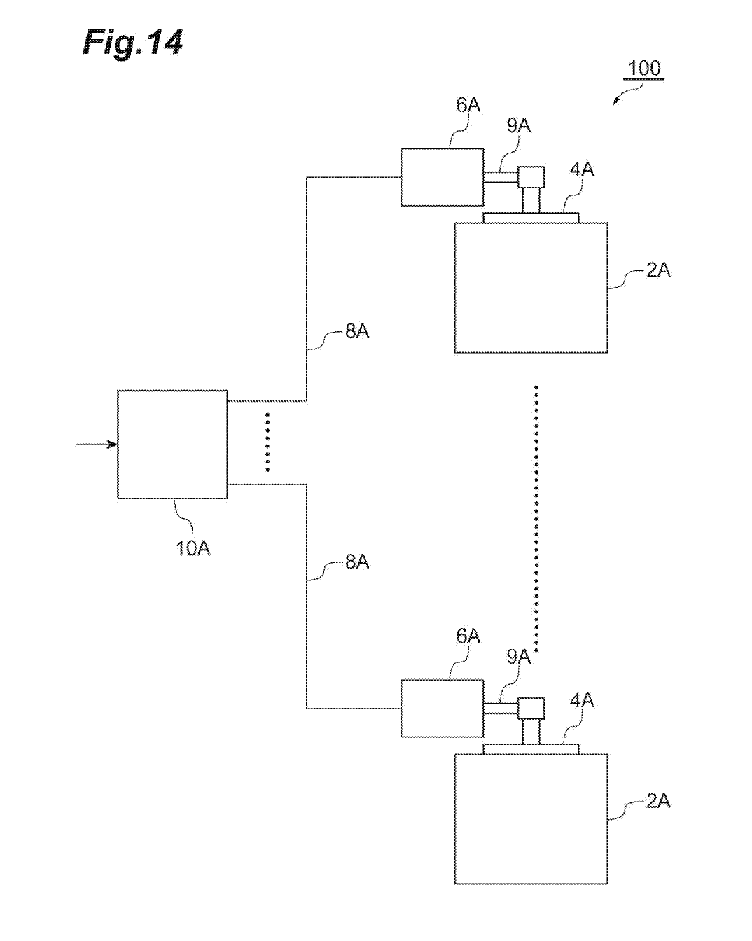

Hereinafter, a plasma processing apparatus according to another exemplary embodiment will be described. FIG. 14 is a diagram schematically illustrating the plasma processing apparatus according to another exemplary embodiment. A plasma processing apparatus 100 illustrated in FIG. 14 is provided with a plurality of chamber bodies 2A, a plurality of antennas 4A, a plurality of microwave generators 6A, a plurality of cables 8A, and a direct-current power supply 10A.

Each of the plurality of chamber bodies 2A is the same chamber body as the chamber body 2 of the plasma processing apparatus 1. Each of the plurality of antennas 4A is the same antennas as the antenna 4 of the plasma processing apparatus 1. Each of the plurality of antennas 4A is combined with a corresponding chamber body so as to introduce a microwave into the corresponding chamber body among the plurality of chamber bodies 2A.

Each of the plurality of microwave generators 6A is the same microwave generator as the microwave generator 6 of the plasma processing apparatus 1. Each of the plurality of microwave generators 6A is connected to a corresponding one antenna among the plurality of antennas 4A through a waveguide part 9A. The waveguide part 9A is the same waveguide part as the waveguide part 9 of the plasma processing apparatus 1.

The plurality of microwave generators 6A is connected to the single direct-current power supply 10A through the respective cables 8A. Each of the plurality of cables 8A is the same cable as the cables 8 of the plasma processing apparatus 1. The direct-current power supply 10A is the same direct-current power supply as the direct-current power supply 10 of the plasma processing apparatus 1. In each of the plurality of microwave generators 6A, the voltage of the direct-current power (the first direct-current power) which is supplied from the direct-current power supply 10A is stepped down by the DC/DC converter 625 of each of the plurality of amplifier modules 621. In each of the plurality of amplifier modules 621, the power (the second direct-current power) having the voltage stepped down by the DC/DC converter 625 is used for the amplification of the high-frequency electric signal by the amplifier 623 and the amplifier 624. In this manner, the direct-current power from the single direct-current power supply 10A may be supplied to the plurality of microwave generators 6A.

From the foregoing description, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A plasma processing apparatus comprising a microwave generator, wherein the microwave generator comprises:
a first module including a distributor configured to distribute a high-frequency electric signal, the first module being configured to output a plurality of high-frequency electric signals;
a second module including a plurality of amplifier modules configured to amplify the plurality of high-frequency electric signals from the first module to output a plurality of microwaves, respectively; and
a combiner configured to combine the plurality of microwaves from the plurality of amplifier modules by spatial combining to output a microwave, and
each of the plurality of amplifier modules has a DC/DC converter configured to step down a voltage of a first direct-current power from an external direct-current power supply to output a second direct-current power, and an amplifier configured to amplify a corresponding high-frequency electric signal among the plurality of high-frequency electric signals from the first module by using the second direct-current power to output a microwave.

2. The plasma processing apparatus according to claim 1, wherein a number of the plurality of amplifier modules is a number which is equal to or larger than a value which is obtained by adding one to a quotient which is obtained by dividing a maximum output power in a specification of the microwave generator by an average value of output power of a maximum operating points of the plurality of amplifier modules.

3. The plasma processing apparatus according to claim 1, wherein the plurality of amplifier modules are evenly arranged along a circumferential direction so as to surround the first module.

4. The plasma processing apparatus according to claim 3, wherein the microwave generator further includes a plurality of heat sinks for cooling the plurality of amplifier modules, and
the plurality of amplifier modules and the plurality of heat sinks are arranged alternately along the circumferential direction.

5. The plasma processing apparatus according to claim 1, wherein the microwave generator further includes a waveform generator configured to generate the high-frequency electric signal.

6. The plasma processing apparatus according to claim 5, wherein the first module includes the waveform generator.

7. The plasma processing apparatus according to claim 1, further comprising:
a direct-current power supply configured to generate the first direct-current power, and
a cable for transmitting the first direct-current power between the direct-current power supply and the plurality of amplifier modules of the microwave generator.

8. The plasma processing apparatus according to claim 7, wherein the cable is a cabtire cable,
the cable satisfies that a weight thereof is 20 kg or less, an outer diameter thereof is 20 mm or less, a minimum bending radius thereof is 100 mm or less, and a withstand voltage thereof is 600 V or less, and
the cable is a multicore cable satisfying that a total cross-sectional area of one or more conductors in the cable is 8 mm² or less.

9. The plasma processing apparatus according to claim 7, further comprising:
a chamber body which provides a chamber; and
an antenna connected to the microwave generator and configured to introduce a microwave to the chamber to excite a gas which is supplied to the chamber.

10. The plasma processing apparatus according to claim 1 wherein a plurality of microwave generators, each of which is the microwave generator, are provided, and
the plasma processing apparatus further comprises:
a direct-current power supply which generates the first direct-current power, and
a plurality of cables for transmitting the first direct-current power between the direct-current power supply and the plurality of amplifier modules of the plurality of microwave generators.

11. The plasma processing apparatus according to claim 10, further comprising:
a plurality of chamber bodies; and
a plurality of antennas connected to the plurality of microwave generators and configured to introduce microwaves to a plurality of chambers provided by the plurality of chamber bodies, respectively, in order to excite a gas which is supplied to the plurality of chambers.
